(19) United States
(12) Patent Application Publication
(10) Pub. No.: US 2023/0367932 A1
(43) Pub. Date: Nov. 16, 2023

(54) ADAPTIVE DENSITY ESTIMATION WITH MULTI-LAYERED HISTOGRAMS

(71) Applicant: Data Culpa, Inc., Carlisle, MA (US)

(72) Inventor: J. Mitchell Haile, Carlisle, MA (US)

(21) Appl. No.: 18/315,935

(22) Filed: May 11, 2023

Related U.S. Application Data
(60) Provisional application No. 63/341,186, filed on May 12, 2022.

(51) Int. Cl. G06F 30/20; G06F 17/18

(52) U.S. Cl. CPC G06F 30/20; G06F 17/18

(57) ABSTRACT

Various embodiments of the present technology relate to data monitoring systems to generate multi-layered histograms. In some examples, the data monitoring system comprises a computing device that stores an executable modeling component. The modeling component, in response to execution, reads a data record associated with a data pipeline and models the data record as a histogram. The histogram comprises histogram buckets that categorize data values of the data record. The modeling component scans the histogram buckets and determines when a proportion of the data values assigned to one of the histogram buckets exceeds a threshold value. When the threshold value is triggered, the modeling component models the data values assigned to the exceeding histogram bucket as a subsidiary histogram. The subsidiary histogram comprises subsidiary histogram buckets that categorize the data values assigned to that histogram bucket.

### CROSS-REFERENCE TO RELATED APPLICATIONS

This U.S. patent application claims priority to U.S. Provisional Patent Application 63/341,186 entitled, “ADAPTIVE DENSITY ESTIMATION WITH MULTI-LAYERED HISTOGRAMS” which was filed on May 12, 2022, and which is hereby incorporated by reference into this U.S. patent application in its entirety.

### TECHNICAL BACKGROUND

A data pipeline comprises a series of data processing elements that intake data from a data source, process the input data for a desired effect, and transfer the processed data to a data target. Data pipelines are configured to intake data that comprises a known format for their data processing elements to operate accurately. When the input data to a data pipeline is altered, the data processing elements may not recognize the changes which can cause malfunctions in the operation of the data pipeline. Changes to input data often arise when the data sets are large. These changes result in a variety of technical issues that exist when processing or ingesting data received through a data pipeline. Implicit schema and schema creep like typos or changes to schema often cause issues when ingesting data. Completeness issues can also arise when ingesting data. For example, completeness can be compromised when there is an incorrect count of data rows/documents, there are missing fields or missing values, and/or there are duplicate and near-duplicate data entries. Additionally, accuracy issues may arise when there are incorrect data types in fields. For example, a string field that often comprises numbers is altered to now comprise words. Accuracy issues may further arise when there are incorrect category field values and incorrect continuous field values. For example, a continuous field may usually have distribution between 0 and 100, but the distribution is significantly different on updated rows or out of our usual bounds. Data pipelines may also have software bugs which impact data quality and data pipeline code is difficult to debug.

Data pipeline monitoring systems are employed to counteract the range of technical issues that occur with data pipelines by detecting when problems arise. Traditional data pipeline monitoring systems employ a user defined ruleset that governs what inputs and outputs for a data pipeline should look like. When data monitoring systems detect inputs and/or outputs of the pipeline are malformed, the monitoring system may alert pipeline operators that an issue has occurred. Data monitoring systems often generate data visualizations like histograms that allow users to visualize the operations of the data pipeline and to model the overall operations of the data pipeline. These histograms lack the resolution needed to produce accurate models of the data pipeline operations. Unfortunately, data monitoring systems do not effectively or efficiently generate histograms for data pipelines.

### Overview

This Overview is provided to introduce a selection of concepts in a simplified form that are further described below in the Detail Description. This summary is not intended to identify key features or essential features of the claimed subject matter, nor is it intended to be used as an aid in determining the scope of the claimed subject matter.

Various embodiments of the present technology generally relate to solutions for modeling data. Some embodiments comprise methods for operating a data monitoring system to generate multi-layered histograms. The method comprises reading a data record associated with a data pipeline and modeling the data record as a histogram wherein the histogram comprises histogram buckets that categorize data values of the data record. The method further comprises scanning the histogram buckets and determining when a proportion of the data values assigned to one of the histogram buckets exceeds a threshold value. When the proportion of the data values assigned to the one of the histogram buckets exceeds the threshold value, the method further comprises modeling the data values assigned to the one of the histogram buckets as a subsidiary histogram wherein the subsidiary histogram comprises subsidiary histogram buckets that categorize the data values assigned to the one of the histogram buckets.

Some embodiments comprise a system to generate multi-layered histograms. The system comprises a memory that stores executable components and a processor. The processor is operatively coupled to the memory and executes the executable components. The executable components comprise a modeling component. In response to executing, the modeling component reads a data record associated with a data pipeline and models the data record as a histogram. The histogram comprises histogram buckets that categorize data values of the data record. The modeling component scans the histogram buckets and determines when a proportion of the data values assigned to one of the histogram buckets exceeds a threshold value. The modeling component models the data values assigned to the one of the histogram buckets as a subsidiary histogram when the proportion of the data values assigned to the one of the histogram buckets exceeds the threshold value. The subsidiary histogram comprises subsidiary histogram buckets that categorize the data values assigned to the one of the histogram buckets.

Some embodiments comprise a non-transitory computer-readable medium storing instructions to generate multi-layered histograms. The instructions, in response to execution by one or more processors, cause the one or more processors to drive a system to perform operations. The operations comprise reading a data record associated with a data pipeline and modeling the data record as a histogram wherein the histogram comprises histogram buckets that categorize data values of the data record. The operations further comprise scanning the histogram buckets and determining when a proportion of the data values assigned to one of the histogram buckets exceeds a threshold value. When the proportion of the data values assigned to the one of the histogram buckets exceeds the threshold value, the operations further comprise modeling the data values assigned to the one of the histogram buckets as a subsidiary histogram wherein the subsidiary histogram comprises subsidiary histogram buckets that categorize the data values assigned to the one of the histogram buckets.

### DESCRIPTION OF THE DRAWINGS

Many aspects of the disclosure can be better understood with reference to the following drawings. The components in the drawings are not necessarily drawn to sale. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 illustrates an exemplary data processing environment to generate multi-layered histograms.

FIG. 2 illustrates an exemplary application to generate multi-layered histograms.

FIG. 3 illustrates an exemplary application to generate multi-layered histograms.

FIG. 4 illustrates an exemplary operation of the data processing environment.

FIG. 5 illustrates an exemplary operation of the data processing environment.

FIG. 6 illustrates an exemplary operation of the data processing environment.

FIG. 7 illustrates an exemplary operation of the data processing environment.

FIG. 8 illustrates an exemplary user interface.

FIG. 9 illustrates an exemplary computing device.

The drawings have not necessarily been drawn to scale. Similarly, some components or operations may not be separated into different blocks or combined into a single block for the purposes of discussion of some of the embodiments of the present technology. Moreover, while the technology is amendable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

The following description and associated figures teach the best mode of the invention. For the purpose of teaching inventive principles, some conventional aspects of the best mode may be simplified or omitted. The following claims specify the scope of the invention. Note that some aspects of the best mode may not fall within the scope of the invention as specified by the claims. Thus, those skilled in the art will appreciate variations from the best mode that fall within the scope of the invention. Those skilled in the art will appreciate that the features described below can be combined in various ways to form multiple variations of the invention. As a result, the invention is not limited to the specific examples described below, but only by the claims and their equivalents.

Various embodiments of the present technology relate to solutions for data monitoring. More specifically, embodiments of the present technology relate to systems and methods for generating multi-layered histograms to perform adaptive density estimation for data produced by a data pipeline. Multi-layered histograms, also referred to as hierarchical histograms, created a layered organization for a data set. When data is concentrated in a particular histogram bin, the overall resolution of the histogram is low. A subsidiary histogram can be generated to categorize the data values assigned to the concentrated histogram bin. This subsidiary histogram is then appended to its parent histogram and provides added data resolution for the data set than what would otherwise be available. A pipeline monitoring system may generate and compare hierarchical histograms for different data sets generated by a data pipeline to track the operation of the data pipeline over time and detect when errors occur in the data pipeline. The pipeline monitoring system may also estimate a probability density function based on the hierarchical histogram to generate a governing model for the data produced by the data pipeline. The pipeline monitoring system compares output data from the pipeline to the model to detect when errors occur in the data pipeline. Now referring to the Figures.

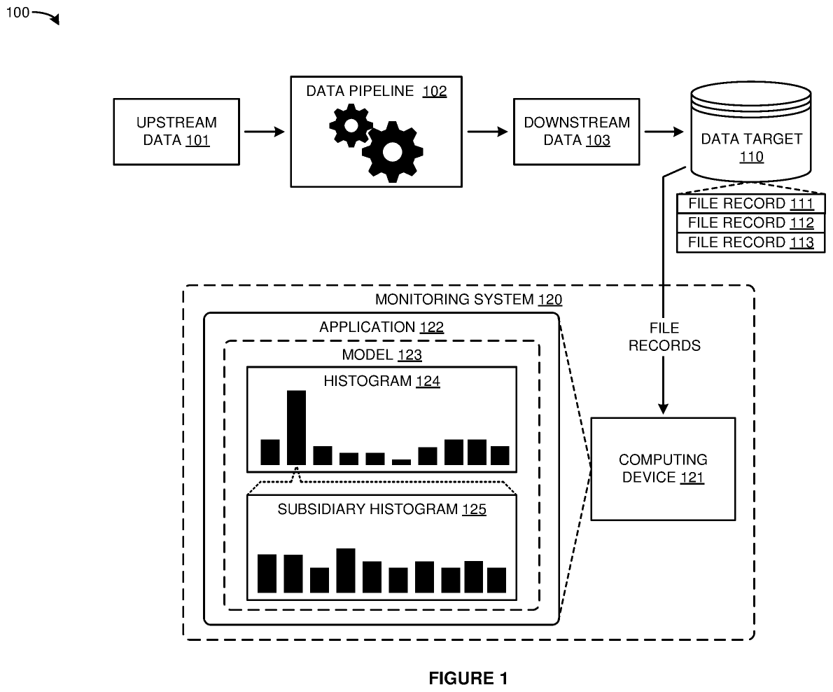

FIG. 1 illustrates data processing environment 100 to model the operations of a data pipeline. Data processing environment 100 provides services like data processing, data cleaning, data enrichment, data storage, data harvesting, and the like. Data processing environment 100 comprises upstream data 101, data pipeline 102, downstream data 103, data target 110, and monitoring system 120. Data target 110 comprises file records 111-113. Monitoring system 120 comprises computing device 121, application 122, model 123, histogram 124, and subsidiary histogram 125. In other examples, data processing environment 100 may include fewer or additional components than those illustrated in FIG. 1. Likewise, the illustrated components of data processing environment 100 may include fewer or additional components, assets, or connections than shown. Each of data pipeline 102, data target 110, and/or monitoring system 120 may be representative of a single computing apparatus or multiple computing apparatuses.

Various operations and system configurations are described herein. In some examples, data pipeline 102 ingests upstream data 101 and writes downstream data 103 to data target 110. Data pipeline 102 is representative of a data processing computing system which intakes “raw” or otherwise unprocessed data and emits processed data (e.g., downstream data 103) configured for consumption by an endpoint (e.g., data target 110). Upstream data 101 may be generated by computing devices of an industrial system, a financial system, research system, another data pipeline, or some other type of system configured to generate data. For example, upstream data 101 may be produced by a computer affiliated with an online transaction service. The computer may generate sales data which characterizes events performed by the online transaction service which is then ingested by pipeline 102 as upstream data 101. It should be appreciated that the type of upstream data ingested by data pipeline 102 is not limited.

Downstream data 103 comprises data generated by the operation of data pipeline 102. Data pipeline 102 comprises one or more computing devices that are connected in series that intake upstream data 101 received from a data source and generate downstream data 103. The one or more computing devices that comprise data pipeline 102 may execute applications to clean, enrich, link, transform, or perform some other operation on upstream data 101 to form downstream data 103. For example, the computing devices of data pipeline 102 may ingest upstream data 101 and execute transform functions on upstream data 101. The execution of the transform functions alters upstream data 101 into a consumable form to generate downstream data 103. For example, upstream data 101 may comprise a non-standard data format and the transform functions may apply a schema to upstream data 101 to generate downstream data 103 which can then be written to data target 110.

Data target 110 is operatively coupled to data pipeline 102. Data target 110 comprises one or more computing systems comprising memory that receive and store downstream data 103 generated by data pipeline 102. For example, data target 110 may comprise a database, data structure, data repository, data lake, and/or some other type of data storage system. Data target 110 maintains file records 111-113. File records 111-113 comprise the downstream data output by pipeline 102 and stored on data target 110. File records 111 may be organized chronologically, by data type, size, source, or some other organizing metric. For example, file records 111 may correspond to a portion of downstream data 103 generated during a first time period (e.g., week one), file records 112 may correspond to a portion of downstream data 103 generated during a second time period (e.g., week two), and file records 113 may correspond to a portion of downstream data 103 generated during a third time period (e.g., week three). Typically, file records 111-113 comprise numeric data values, however file records 111-113 may comprise other data types like strings.

Monitoring system 120 comprises computing device 121 which is operatively coupled to data target 110. Monitoring system 120 provides services like pipeline monitoring, pipeline output modeling, and pipeline operator alerting. Monitoring system 120 may comprise a cloud computing system, a hybrid-cloud, a data center, and the like. For example, monitoring system 120 may comprise a cloud computing service with a distributed computing architecture. In such examples, computing device 121 may be representative of a distributed computing system that provides the computing power for the cloud service. Although computing device 121 is illustrated as a physical computing device, portions of computing device 121 may comprise a virtualized computing system like a virtual machine. Computing device 121 hosts application 122 to model and monitor the operations of data pipeline 102. It should be appreciated that the specific number of applications/modules represented as application 122 and hosted by computing device 121 is not limited. Exemplary applications hosted by computing device 121 include Data Culpa Validator and the like. Computing device 121 may comprise user interface elements like a display, keyboard, touchscreen, tablet, and the like. Computing device 121 may render a display of application 122 on the user interface thereby allowing a user to interact with application 122 to view the status of data pipeline 102.

Application 122 may model the shape, probability density, volume, value ranges, schemas, statistical attributes, and/or other qualities of the data streams output/ingested by data pipeline 102. Application 122 may monitor a table in a data warehouse or records for data pipeline 102 that are being copied to application 122. As application 122 monitors the data streams generated by data pipeline 102, application generates model 123 to determine a probability density estimation for the outputs generated by pipeline 102. Model 123 comprises histograms 124 and 125 which form a multi-layered or hierarchical histogram. Application 122 uses histograms 124 and 125 to calculate the probability density estimate of pipeline outputs which can be used to detect when the pipeline outputs become erroneous. For example, application 122 may compare the data values of a file record (e.g., file record 111) to the probability density estimation and determine the operation of data pipeline 102 has changed when the data values do not fit the density estimation. Histograms 124-125 comprise histogram buckets that categorize data generated by data pipeline 102 and saved to data target 110 as file records 111-113. Typically, the histogram buckets categorize the data values by range.

Histogram 125 is a subsidiary histogram of histogram 124 and comprises a set of histogram buckets that categorize the data values of an individual bucket of histogram 124. Application 122 may generate histogram 125 in response to determining the proportion of data values categorized by one or more histogram buckets of histogram 124 is greater than a proportion threshold. The threshold sets a limit to the maximum proportion of the total amount of data values that can be assigned to a single histogram bucket. For example, the threshold may comprise 10% of the total data items. The subsidiary histogram enhances the resolution of the modeled data set.

Data pipeline 102, data target 110, and computing device comprise microprocessors, software, memories, transceivers, bus circuitry, and the like. The microprocessors comprise Central Processing Units (CPU), Graphical Processing Units (GPU), Application-Specific Integrated Circuits (ASIC), Field Programmable Gate Array (FPGA), and/or types of processing circuitry. The memories comprise Random Access Memory (RAM), Solid State Drives (SSD) non-Volatile Memory Express (NVMe) SSDs, Hard Disk Drives (HDDs), and/or the like. The memories store software like operating systems, machine code, user applications, application 122, data analysis applications, and data processing functions. The microprocessors retrieve the software from the memories and execute the software to drive the operation of data processing environment 100 as described herein. The communication links that support connect the elements of data processing system use metallic links, glass fibers, radio channels, or some other communication media. The communication links use Time Division Multiplex (TDM), Data Over Cable System Interface Specification (DOCSIS), Internet Protocol (IP), General Packet Radio Service Transfer Protocol (GTP), Institute of Electrical and Electron Engineers (IEEE) 802.11 (WIFI), IEEE 802.3 (ENET), virtual switching, inter-processor communication, bus interfaces, and/or some other data communication protocols. Data pipeline 102, data target 110, and computing device 121 may exist as unified computing devices and/or may be distributed between multiple computing devices across multiple geographic locations.

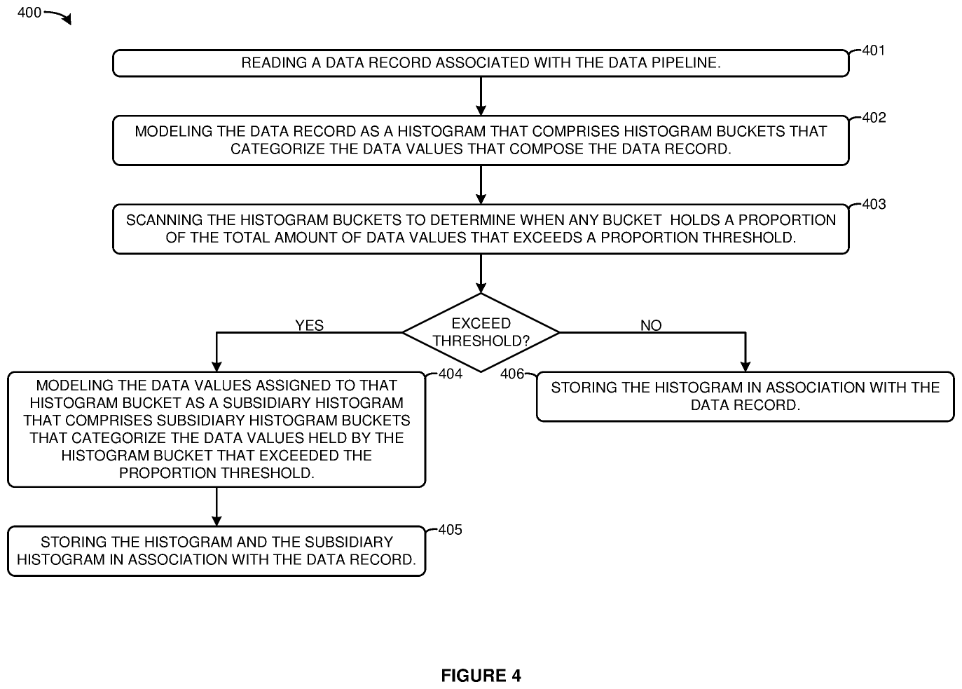

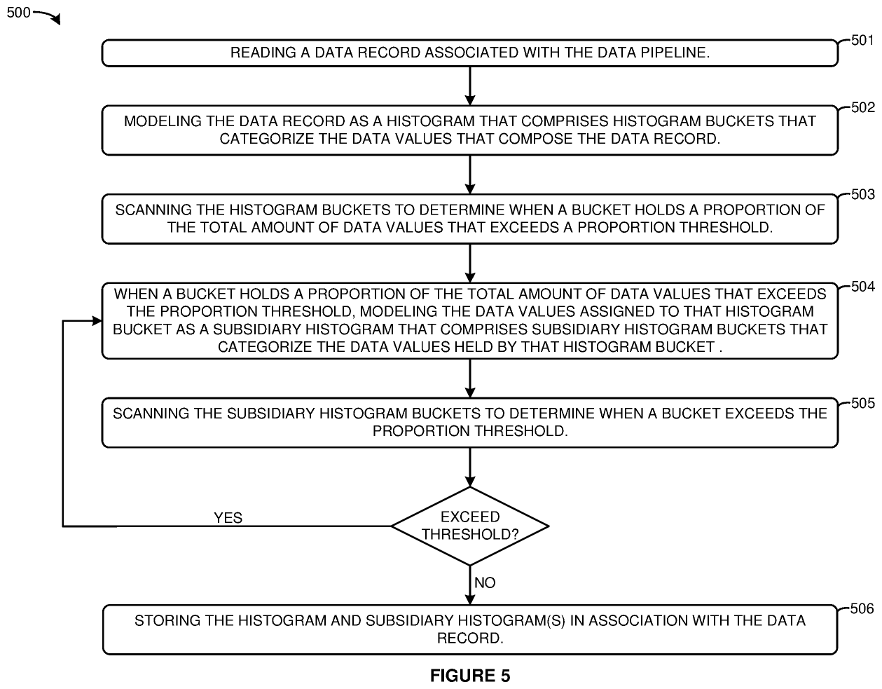

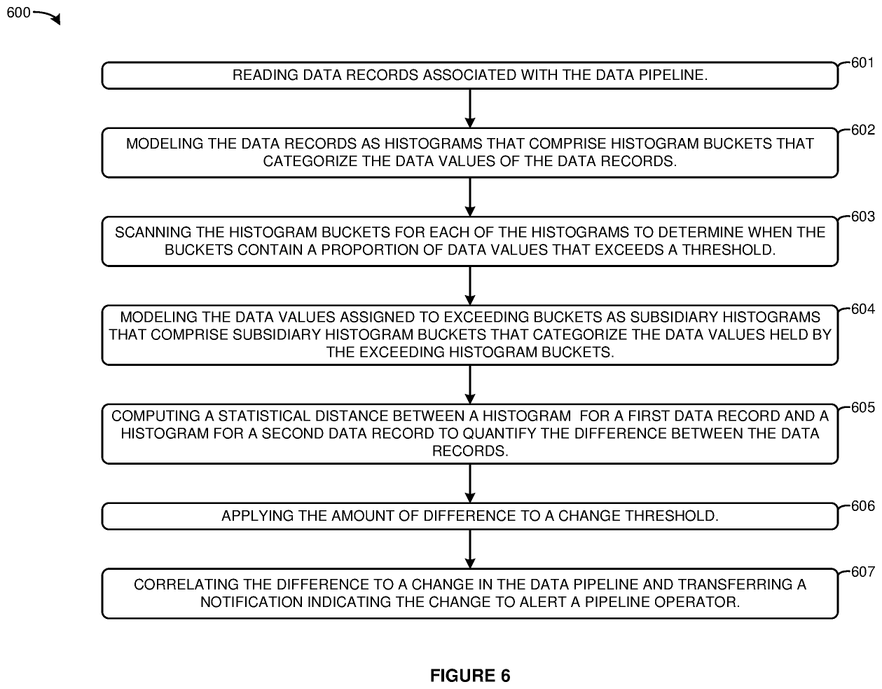

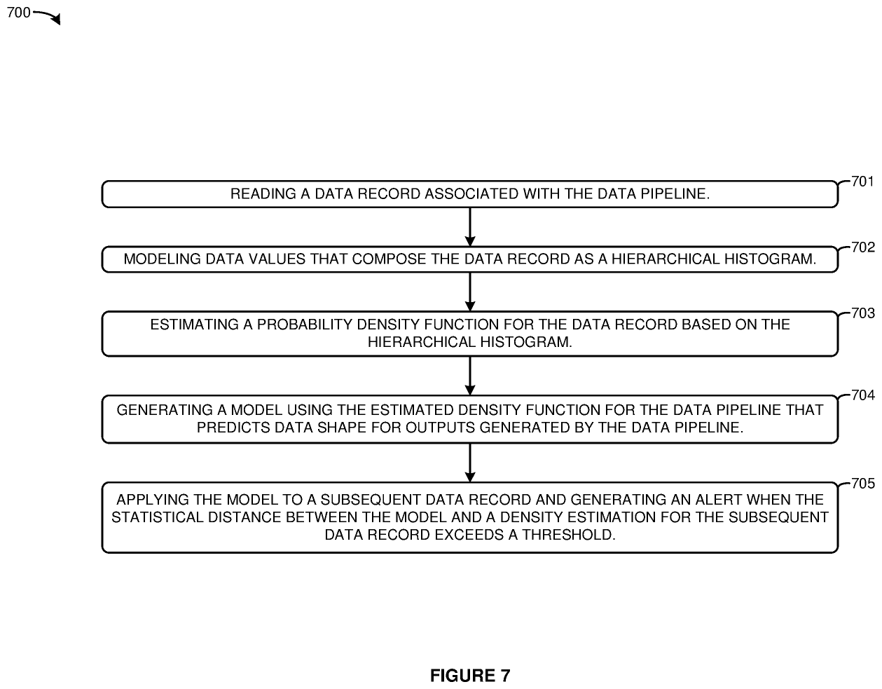

In some examples, data processing environment 100 implements process 400 illustrated in FIG. 4, process 500 illustrated in FIG. 5, process 600 illustrated in FIG. 6, and/or process 700 illustrated in FIG. 7. It should be appreciated that the structure and operation of data processing environment 100 may differ in other examples.

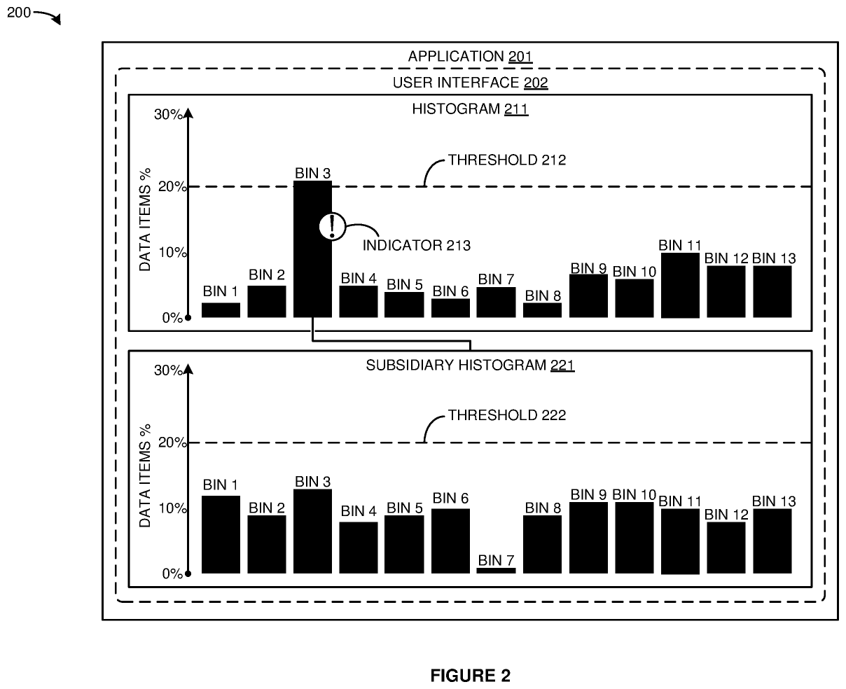

FIG. 2 illustrates environment 200 which comprises application 201. Application 201 is an example of application 122 illustrated in FIG. 1, however application 122 may differ. Application 201 generates data to render user interface 202 which comprises histogram 211 and subsidiary histogram 221 which together form a hierarchical histogram. The x-axis of histogram 211 comprises bins 1-13 which correspond to data value ranges. The y-axis of histogram 211 indicates the percentage of total data values in each of bins 1-13. As illustrated in FIG. 2, as the vertical height of the bins increases, the proportion of data values represented by that bin (e.g., the data value counts) increases. Histogram 211 further comprises threshold 212 and indicator 213. In this example, bin 3 exceeds threshold 212. In response, application 201 generates subsidiary histograms 221 using the data values assigned to bin 3 and marks bin 3 with indicator 213. A user may select indicator 213 to view subsidiary histogram 221. Subsidiary histogram 221 comprise bins 1-13 and threshold 222. In this example, none of the bins of histogram 221 exceed item threshold 222. However, if one or more of the bins of subsidiary histogram 221 exceeded item threshold 222, application 201 may generate additional subsidiary histograms to further expand the resolution of the data set. It should be appreciated that the number of histogram layers nor the number of subsidiary histograms in a layer that form the hierarchical histogram are not limited. For example, the hierarchical histogram may comprise five histogram layers.

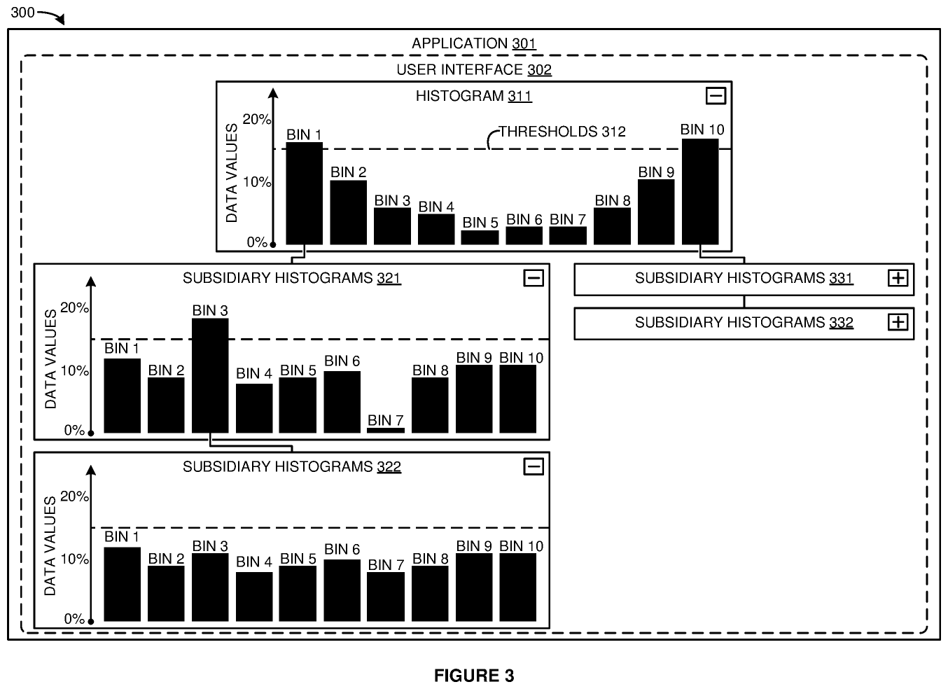

FIG. 3 illustrates environment 300 which comprises application 301. Application 301 is an example of application 122 illustrated in FIG. 1, however application 122 may differ. Application 301 generates data to render user interface 302 which comprises histogram 311 and subsidiary histograms 321, 322, 331, and 332 which together form a hierarchical histogram. The x-axis of histogram 311 comprises bins 1-10 which correspond to data value ranges. The y-axis of histogram 311 indicates the percentage of total data values in each of bins 1-13. As illustrated in FIG. 3, as the vertical height of the bins increases, the proportion of data values represented by that bin increases. Histograms 311, 321, 322, 331, and 332 further comprise thresholds 312. Similar to application 201, application 301 generates subsidiary histograms 321, 322, 331, and 332 for the histogram bins that categorize a proportion of data values that exceeds the threshold. User interface 302 comprises toggles that allow a user to collapse the view of any of the histograms. In this example, subsidiary histograms 331-332 are collapsed. In some examples, application 301 may represent one or more bins of subsidiary histograms 321, 322, 331, and 332 as a single instance storage. Typically, this occurs when the majority of values categorized by a bin comprise the same value. By representing a bin a single value, processing errors are reduced while the information represented by the bin is maintained.

FIG. 4 illustrates process 400. Process 400 comprises a multi-layered histogram generation process. Process 400 may be implemented in program instructions in the context of any of the software applications, module components, or other such elements of one or more computing devices. The program instructions direct the computing devices(s) to operate as follows, referred to in the singular for the sake of clarity.

The operations comprise reading a data record associated with the data pipeline (step 401). The operations further comprise modeling the data record as a histogram that comprises histogram buckets that categorize the data values that compose the data record (step 402). The operations further comprise scanning the histogram buckets to determine when any bucket holds a proportion of the total amount of data values that exceeds a proportion threshold (step 403). If the threshold is exceeded, the operation continues by modeling the data values assigned to that histogram bucket as a subsidiary histogram that comprises subsidiary histogram buckets that categorize the data values held by the histogram bucket that exceeded the proportion threshold (step 404). The operations further comprise storing the histogram and the subsidiary histogram in association with the data record (step 405). If the proportion threshold was not exceeded, the operations continue by storing the histogram in association with the data record (step 406).

Referring back to FIG. 1, data processing environment 100 includes a brief example of process 400 as employed by one or more applications hosted by computing device 121. The operation may differ in other examples.

In some examples, data pipeline 102 receives upstream data 101 generated by a data source. For example, data pipeline 102 may exist in a data pipeline ecosystem and data pipeline 102 may ingest upstream data 101 that was output by another pipeline in the ecosystem. Data pipeline 102 processes upstream data 101 to produce downstream data 103. For example, data pipeline 102 may execute a series of data processing steps to transform upstream data 101 into a standardized form configured for storage on data target 110. Data pipeline 102 may comprise a series of data processing devices that generate data streams as they process upstream data 101 into downstream data 103. For example, a first one of the computing devices may ingest upstream data 101 and generate an output data stream. A subsequent one of the computing devices may ingest the output data stream generated by the first one of the computing devices and generate its own output data stream. This process may continue to a final one of the computing devices which generates downstream data 103. Data pipeline 102 writes downstream data 103 to data target 110 to generate file records 111-113. In this example file records 111-113 correspond to different chronological time periods and comprise numeric data values generated by data pipeline 102 during the respective time periods.

Data target 110 calls application 122 hosted by computing device 121 to process file record 111. Application 122 acknowledges the call and data target 110 copies file record 111 to application 122. Application 122 may comprise an Application Programming Interface (API) to facilitate communication between itself and data target 110 and/or data pipeline 102. For example, data target 110 may call the API of application 122 to ingest file record 111. Application 122 receives the copy of file record 111 reads the data values of file record 111 (step 401). Application 122 determines counts for each of the data values of file record 111. Application 122 categorizes the numeric data values of file record 111 by data range to model file record 111 as histogram 124 (step 402). Histogram 124 comprises a set of histogram buckets that correspond to the data ranges that indicate the counts for each of the data values. For example, one of the data ranges may comprise a first quartile. Data values that fall within the first quartile are assigned to the histogram bucket that corresponds to the first quartile which quantifies that counts of those data values. Each histogram bucket indicates the amount of data values that reside within the data value range that corresponds to that bucket. By representing file record as a histogram, application 122 greatly reduces the amount of data needed to model file record 111. For example, file record 111 may comprise more than one million data values of which 10,000 comprise unique data values. By only modeling the counts of the unique data values as histogram 124, application 122 accurately depicts file record 111 without needing to plot and process every data value that comprises file record 111. The reduced data set size reduces the required computing resources to model file record 111 thereby improving the operating efficiency of computing device 121. For example, the reduced data set size may reduce the memory occupancy and processor load of computing device 121. Moreover, by reducing the required computing resources, the economic cost and the amount of time needed to accurately model file record 111 is also reduced.

Once every data value of file record 111 has been categorized, application 122 scans the histogram buckets to determine if the proportion of the total data values assigned to an individual bucket exceeds a proportion threshold (step 403). Application 122 may determine the threshold based on histogram 124, the threshold may comprise a preset value, or the threshold may be user configured. Application 122 may correlate the number of bins that comprise histogram 124 to a proportion threshold. For example, if histogram 122 comprises ten buckets, application 122 may select a proportion threshold of 10%. In this case, if the amount of data values assigned to a single histogram bucket comprise more than 10% of the total data values, that histogram bucket would exceed the proportion threshold. It should be appreciated that this threshold percentage is exemplary and may vary in other examples. In other examples, the threshold may define an absolute limit instead of a proportional limit. For example, a user may define an absolute threshold of 1,000 data values. In this case, if the amount of data values assigned to a single histogram bucket exceeds 1,000 data values, that histogram bucket would exceed the absolute threshold. It should be appreciated that the threshold depends in part on the amount of data and/or the type of data and that the specific type of threshold is not limited.

When application 122 determines one or more buckets of histogram 124 exceeds the threshold, application 122 models the data values assigned to that bucket as subsidiary histogram 125 (step 404). When application 122 determines none of the buckets of histogram 124 exceeds the threshold, application 122 stores histogram 124 in association with file record 111 (step 406). Subsidiary histogram 125 comprises subsidiary histogram buckets that categorize the data values assigned to the exceeding bucket of histogram 124 by data value range. To generate subsidiary histogram 125, application 122 determines the counts of the data values assigned to the exceeding bucket of histogram 124. Application 122 selects a new set of data value ranges based on the value range assigned to the exceeding bucket and the counts of the values categorized by the bucket. Application 122 categorizes the numeric data values of the exceeding bucket by the new data ranges to model the exceeding bucket as subsidiary histogram 125. Each subsidiary histogram bucket indicates the counts of the data values that reside within the value range that corresponds to that bucket.

Application 122 appends subsidiary histogram 125 to histogram 124 at the exceeding bucket to form model 123. Model 123 comprises a hierarchical histogram. Application 122 stores model 123 in association with file record 111 to model the operation of pipeline 102 over the time period that file record 111 was generated (step 405). The hierarchical histogram comprising histograms 124 and 125 provides an enhanced view of file record 111 than what would otherwise be available with a traditional histogram and further reduces the space needed to depict file record 111. The enhanced view allows application 122 to more accurately model (e.g., determine density estimations) the operations of pipeline 102. Application 122 may display model 123 on the user interface systems of computing device 121 for review by a user to visualize the operations of data pipeline 102. In some examples, file record 111 may comprise data generated by multiple sources. Application 122 may tag the hierarchical histogram with metadata to track the sources.

To further increase the resolution of that hierarchical histogram, in some examples application 122 may determine a set of most popular values in file record 111. Application 122 determines the counts, or the total number of times each of the set of most popular values appears in file record 111. For example, the set of most popular values may comprise the 50 most popular values in file record 111. Application 122 generates a single instance storage for each of the set of most popular values for file record 113. In computing, a single instance storage is a single shared data value to represent a set of identical or substantially similar data values. Application 122 may subtract the single instance storage values from the hierarchical histogram comprises histograms 124 and 125 to generate a residual histogram. The residual histogram provides an alternate view of file record 111 to emphasize the shape of the data when the most common data values are removed. For example, the view of statistical noise in a data set may be obscured when every value in the set is represented in a histogram. By removing those most common data values, application 122 better characterizes the statistical noise present in file record 111. Application 122 may append a list of the single instance storages for the set of most popular values on the residual histogram to illustrate the relationship between the most common data values and the remainder of the data set. In some examples, application 122 utilizes single instance storage for infrequent values in file record 113 to save computing resources. For example, application 122 may represent data values with counts less than ten as single instances.

Advantageously, monitoring system 120 effectively and efficiently generates hierarchical histograms to enhance the resolution of histograms representing the operation of a data pipeline and improve the accuracy of statistical models of data pipeline 102 derived from the hierarchical histograms. The hierarchical histograms increase the accuracy of models for pipeline 102 and reduce the space needed to display the histograms while maintaining the resolution of the histogram. Moreover, the hierarchical histogram resolution is adaptive and allows for algebraic operations between histograms while reducing information loss. The reduced data set size of the hierarchical histograms when compared to their file records saves computing resources to improve the efficiency of computing operations and reduces the time and cost to model the outputs from a data pipeline.

FIG. 5 illustrates process 500. Process 500 comprises a multi-layered histogram generation process. Process 500 may be implemented in program instructions in the context of any of the software applications, module components, or other such elements of one or more computing devices. The program instructions direct the computing devices(s) to operate as follows, referred to in the singular for the sake of clarity.

The operations comprise reading a data record associated with the data pipeline (step 501). The operations further comprise modeling the data record as a histogram that comprises histogram buckets that categorize the data values that compose the data record (step 502). The operations further comprise scanning the histogram buckets to determine when any bucket holds a proportion of the total amount of data values that exceeds a proportion threshold (step 503). When a bucket holds a proportion of the total amount of data values that exceeds the proportion threshold, the operations further comprise modeling the data values assigned to that histogram bucket as a subsidiary histogram that comprises subsidiary histogram buckets that categorize the data values held by that bucket (step 504). The operations further comprise scanning the subsidiary histogram buckets to determine when a bucket exceeds the proportion threshold. If any of the subsidiary buckets exceed the proportion thresholds, process 500 returns to step 504. If none of the subsidiary buckets exceed the proportion threshold, the operations continue by storing the histogram and subsidiary histogram(s) in association with the data record (step 506).

Referring back to FIG. 1, data processing environment 100 includes a brief example of process 500 as employed by one or more applications hosted by computing device 121. The operation may differ in other examples.

In some examples, data target 110 calls an API of application 122 hosted by computing device 121 to process file record 112. The API accepts the call and data target 110 copies file record 112 to application 122. Application 122 reads the data values of file record 112 (step 501) and categorizes the numeric data values by range to model file record 112 as histogram 124 (step 502). Once every data value of file record 112 has been categorized, application 122 scans the histogram buckets to determine if the proportion of the total data values assigned to an individual bucket exceeds a proportion threshold (step 503). In this example, the proportion threshold comprises a value of 10%. Application 122 determines the total amount of data values and compares the amount of data values categorized by each of the buckets to the total amount of data values to determine the proportions. For example, application 122 may enter the counts for each bucket and the total amount of data values of file record 112 into a data structure that outputs proportions for each bucket.

Application 122 detects that one of the histogram buckets categorizes more than 10% of the total data values. In response, application 122 models the data values assigned to that bucket as subsidiary histogram 125 (step 504). Application 122 identifies the value range of the exceeding histogram bucket and calculates a new set of value ranges for the subsidiary histogram buckets. For example, application 122 may correlate the range size of the exceeding bucket to a new set of ranges that, when combined, cover the entire data value range of the exceeding bucket. Application 122 categorizes the numeric data values of the exceeding bucket by the new data ranges to model the exceeding bucket as subsidiary histogram 125. Application 122 appends subsidiary histogram 125 to histogram 124 at the exceeding bucket to form a hierarchical histogram.

Application 122 scans the subsidiary histogram buckets to determine if the proportion of the total data values assigned to an individual subsidiary bucket exceeds a proportion threshold (step 505). Application 122 may use the same proportion threshold or a new proportion threshold when scanning subsidiary histograms. Application 122 detects that one of the subsidiary histogram buckets categorizes more than 10% of the total data values. In response, application 122 models the data values assigned to that subsidiary bucket as an additional subsidiary histogram appended to subsidiary histogram 125 at the exceeding subsidiary bucket to form a three-layered hierarchical histogram. Application 122 determines the second subsidiary histogram does not exceed the proportion threshold, however in other examples, application 122 may generate more subsidiary histograms until the threshold is no longer exceeded.

The three-layered hierarchical histogram forms model 123. Application 122 stores model 123 in association with file record 112 to model the operation of pipeline 102 over the time period that file record 112 was generated (step 506). Application 122 may display model 123 on the user interface systems of computing device 121 for review by a user to visualize the operations of data pipeline 102.

FIG. 6 illustrates process 600. Process 600 comprises a multi-layered histogram generation process. Process 600 may be implemented in program instructions in the context of any of the software applications, module components, or other such elements of one or more computing devices. The program instructions direct the computing devices(s) to operate as follows, referred to in the singular for the sake of clarity.

The operations comprise reading data records associated with the data pipeline (step 601). The operations further comprise modeling the data records as histograms that comprise histogram buckets that categorize the data values of the data records (step 602). The operations further comprise scanning the histogram buckets for each of the histograms to determine when the buckets contain a proportion of data values that exceeds a threshold (step 603). The operations further comprise modeling the data values assigned to the exceeding buckets as subsidiary histograms that comprise subsidiary histogram buckets that categorize the data values held by the exceeding histogram buckets (step 604). The operations further comprise computing a statistical distance between a histogram for a first data record and a histogram for a second data record to quantify the difference between the data records (605). The operations further comprise applying the amount of difference to a change threshold (step 606). The operations further comprise correlating the difference to a change in the data pipeline and transferring a notification indicating the change to alert a pipeline operator (step 607).

Referring back to FIG. 1, data processing environment 100 includes a brief example of process 600 as employed by one or more applications hosted by computing device 121. The operation may differ in other examples.

In some examples, data target 110 calls application 122 to ingest file records 112 and 113. Application 122 reads the data values of file records 112 and 113 (step 601) and categorizes the numeric data values by data range to model file records 112 and 113 as histograms (step 602). Once every data value of file records 112 and 113 has been categorized, application 122 scans the histogram buckets to determine if the proportion of the total data values assigned to an individual bucket exceeds a proportion threshold (step 603). Application 122 compares the amount of data values categorized by each of the buckets to the total amount of data values to determine the proportions. Application 122 enters the counts for each bucket and the total amount of data values of file records 112 and 113 into a data structure that outputs proportions for each bucket. Application 122 detects that one of the histogram buckets for each histogram categorizes more than 15% of the total data values thereby exceeding a proportion threshold. In response, application 122 models the data values assigned to exceeding buckets as subsidiary histograms to form hierarchical histograms for file record 112 and file record 113 (step 604).

Application 122 calculates a statistical distance between the hierarchical histogram modeling file record 112 and the hierarchical histogram for file record 113 (step 605). In this example, file record 112 comprises data output by pipeline 102 during a chronologically first time period and file record 113 comprises data output by pipeline 102 during a chronologically subsequent time period. The statistical distance may comprise a geometric distance, a Jaccard distance, a Hamming distance, an edit distance, or some other type of statistical measurement to quantify the difference between two data sets. Typically, as the similarity between file record 112 and file record 113 increases, the statistical distance between the two sets decreases. Likewise, as the similarity between file records 112 and 113 decreases, the statistical distance between the two sets increases. Conventional histogram comparison algorithms are based on “earth mover distance” however they are inadequate due to the large amount of information loss. The hierarchical representation of file records 112 and 113 allows application 122 to generate more accurate results than single layered histogram algorithms. The hierarchy auto-adjustment reduces space while also increasing detail. In some examples, application 122 may compare median-to-median distance between the histograms for file records 112 and 113. If the medians for two histograms are the same, application 122 may determine the statistical distance between the subsidiary histograms to detect changes between file records 112 and 113.

Application 122 applies the measured statistical distance to a change threshold (step 606). The change threshold defines the maximum allowable statistical difference between two data steps. The change threshold may be user configured or may comprise a preset value. For example, a user may select a particular geometric distance as the threshold. A lower change threshold allows for lower amount of difference between the file records while a high change threshold allows for a greater amount of difference between the file records. When the amount of difference triggers the threshold, application 122 correlates the difference to a change in data pipeline 102 and notifies pipeline operators of the change. For example, the notification may indicate the operational time period when the first file record was generated (e.g., file record 112), the operational time period when the subsequent file record was generated (e.g., file record 113), and state that the operation of data pipeline 102 changed between these two time periods. Typically, a large difference between two file records indicates a problem in the data pipeline. For example, the upstream data consumed by the pipeline may be malformed (e.g., missing fields) causing the pipeline to behave erroneously or a software glitch in one or more of the computing devices that comprise the data pipeline may cause the pipeline to behave erroneously. The erroneous behavior often results in the downstream data produced from the data pipeline changing with respect to previous pipeline outputs. In response to receiving the notification, the pipeline operator, or an autonomous pipeline control system for pipeline 102 may update the pipeline (e.g., software update) to address the detected pipeline anomaly.

FIG. 7 illustrates process 700. Process 700 comprises a multi-layered histogram generation process. Process 700 may be implemented in program instructions in the context of any of the software applications, module components, or other such elements of one or more computing devices. The program instructions direct the computing devices(s) to operate as follows, referred to in the singular for the sake of clarity.

The operations comprise reading a data record associated with the data pipeline (step 701). The operations further comprise modeling data values that compose the data record as a hierarchical histogram (step 702). The operations further comprise estimating a probability density function for the data record based on the hierarchical histogram (step 703). The operations further comprise generating a model using the estimated density function for the data pipeline that predicts data shape for outputs generated by the data pipeline (step 704). The operations further comprise applying the model to a subsequent data record and generating an alert when the statistical distance between the model and a density estimation for the subsequent data record exceeds a threshold (step 705).

Referring back to FIG. 1, data processing environment 100 includes a brief example of process 700 as employed by one or more applications hosted by computing device 121. The operation may differ in other examples.

In some examples, application 122 ingests a copy of file record 111 and reads the data values of file record 111 (step 701). Application 122 models the data values that compose file record 111 as a hierarchical histogram (702). For example, application 122 may generate a hierarchical histogram for file record 111 as described in the previous Figures. Once the generated, application 122 estimates a probability density function for file record 111 based on the hierarchical histogram (703). The probability density function indicates a likelihood that a randomly selected data value of file record 111 will possess a given data value. The density function also illustrates the shape of file record 111. Exemplary probability density functions include normal density functions, geometric density functions, exponential density functions, and the like. To estimate the density function, application 122 fits a curve to the hierarchical histogram and calculates a mathematical representation (e.g., a function) for the curve. By increasing the resolution of the histogram, the accuracy of the density estimation is also increased improving the ability of monitoring system 120 to model the operation of pipeline 102.

Application 122 generates model 123 using the density estimation for file record 111 to detect deviations in subsequent outputs from data pipeline 102 (step 704). Model 123 may comprise the density function curve and a deviation tolerance that indicates how much a subsequent data set can differ before an alert is generated. For example, the deviation tolerance may comprise a preset threshold with a statistical distance (e.g., a geometric distance) as the threshold value. For example, data sets that comprise a statistical distance from model 123 that exceeds the threshold may drive application 122 to transfer an alert for display on a pipeline operator's computer system to indicate the deviation. Likewise, data sets that comprise a statistical distance from model 123 that does not exceed the threshold may drive application 122 to transfer a notification for display on a pipeline operator's computer system that that indicates the pipeline is operating normally.

Application 122 ingests a copy of file record 113 and reads the data values of file record 113. In this example, file record 113 comprises a subsequently generated pipeline output, however in other examples, file record 113 may be generated at some other point in time with relation to file record 111. Application 122 models the data values that comprise file record 113 as a hierarchical histogram and estimates a probability density function for file record 113 based on the hierarchical histogram. Application 122 applies model 123 to file record 113 by calculating a statistical distance between the subsequent density function for file record 113 to the density function of model 123 (step 705). Application 122 compares the statistical distance to the deviation threshold of model 123 to determine if the data values generated by pipeline 102 that comprise file record 113 differ significantly (e.g., the numerical shape of the data set) from the modeled behavior of pipeline 102. When the observed statistical distance exceeds the change threshold, application 122 generates and transfers an alert for display on pipeline operator computing systems that indicates the erroneous behavior of pipeline 102. The pipeline operator or an automated system may then take corrective action, (e.g., implement a software update for pipeline 102) to correct the detected pipeline behavior.

It should be appreciated that processes 400, 500, 600, and 700 comprise examples of one another and that in some examples, one or more of processes 400, 500, 600, and 700 may be combined. Processes 400, 500, 600, and 700 may differ in other examples.

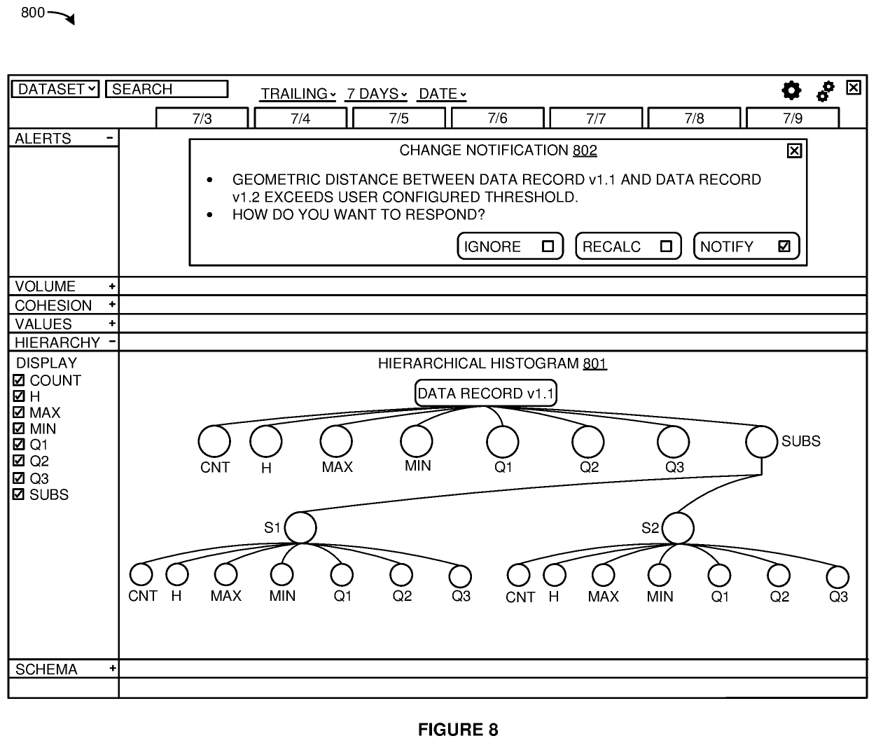

FIG. 8 illustrates user interface 800. User interface 800 comprises an example of application 122, however application 122 may differ. For example, application 122 may generate data for rendering user interface 800 as illustrated in FIG. 8. User interface 800 comprises a pipeline monitoring application presented on a display screen which is representative of any user interface for modeling data sets associated with a data pipeline as hierarchical histograms. User interface 800 comprises a GUI configured to allow a user to view operational metrics for a data pipeline like data volume and data shape, to assess hierarchical histograms, and to receive notifications regarding detected errors in the operations of the data pipeline. The GUI provides visualizations for a hierarchical histogram that categorizes the data output of a data pipeline.

The top panel of user interface 800 is representative of a navigation panel and comprises tabs like “dataset” and “search” that allows a user to find and import data sets into user interface 800. For example, a user may interact with the “dataset” tab to import a data set from a data storage system that receives the outputs of the pipeline. The top panel also includes date range options to select a data set from a period of time. In this example, a user has selected to view a data set over a week ranging from July 3^{rd} to July 9^{th} labeled as 7/3-7/9 in user interface 800. In other examples, a user may select a different date range and/or a different number of days. The left side panel of user interface 800 comprises tabs labeled alerts, volume, cohesion, values, hierarchy, and schema. In other examples, the left side panel may comprise different tabs than illustrated in FIG. 8. When a user selects one of the tabs, the tab expands to reveal its contents. In this example, a user has opened the alerts tab and the hierarchy tab. The hierarchy tab opens hierarchical histogram 801 and a set of display options. The alerts tab opens change notification 802. The display options allows the user to customize the view of hierarchical histogram 801. The display options include toggles labeled count, h, max, min, q1, q2, q3, and subs. In other examples, the display options may differ.

Hierarchical histogram 801 is a model of a data record. Histogram 801 comprise bins for a maximum range (max), minimum range (min), 1^{st} quartile (q1), 2^{nd} quartile (q2), and 3^{rd} quartile (q3). Subsidiary histograms s1 and s2 are appended to the parent histogram at the subs tab. A user may select the histogram bins to review their contents and/or other data that characterizes the data record. Change notification 802 is representative of an alert for a pipeline operator. Change notification 802 states the geometric distance between two data records exceeds a user configured threshold. The application that renders user interface 802 may generate change notification 802 in response to calculating the geometric distance between hierarchical histograms for the data sets and determining the geometric distance exceeds a user defined threshold. As explained in the preceding Figures, when a significant difference is observed between two output data sets of a data pipeline, this can indicate an error has occurred in the computing devices that compose the data pipeline or in the data inputs to the data pipeline. Change notification 802 comprises user selectable options to either ignore the notification, recalculate the geometric distance, or to transfer a notification. In this example, a user has selected the option to transfer the notification.

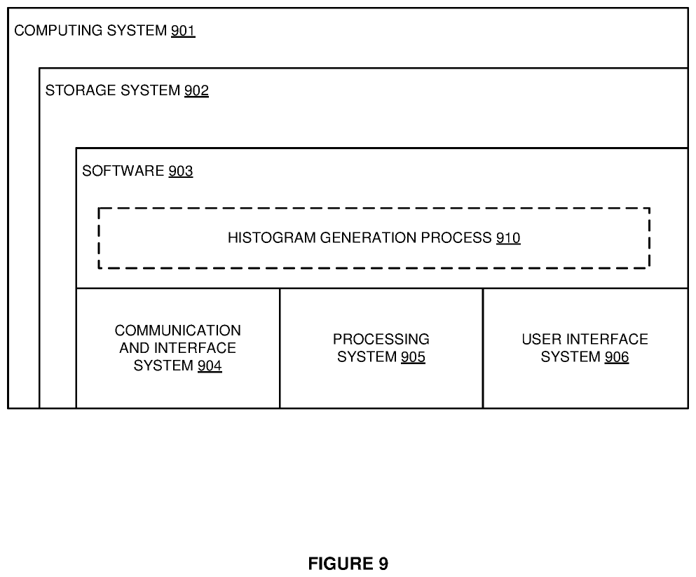

FIG. 9 illustrates computing device 901. Computing device 901 is representative of any system or collection of systems in which the various processes, programs, services, and scenarios disclosed herein for visualizing data generated by a data pipeline. For example, computing device 901 may be representative of data pipeline 102, data target 110, computing device 121, and/or any other computing system contemplated herein. Examples of computing system 100 include, but are not limited to, server computers, routers, web servers, cloud computing platforms, and data center equipment, as well as any other type of physical or virtual server machine, physical or virtual router, container, and any variation or combination thereof.

Computing system 901 may be implemented as a single apparatus, system, or device or may be implemented in a distributed manner as multiple apparatuses, systems, or devices. Computing system 901 includes, but is not limited to, storage system 902, software 903, communication and interface system 904, processing system 905, and user interface system 906. Processing system 905 is operatively coupled with storage system 902, communication interface system 904, and user interface system 906.

Processing system 905 loads and executes software 903 from storage system 902. Software 903 includes and implements histogram generation process 910, which is representative of the hierarchical histogram generation and density estimation processes discussed with respect to the preceding Figures. For example, process 910 may be representative of process 400 illustrated in FIG. 4, process 500 illustrated in FIG. 5, process 600 illustrated in FIG. 6, process 700 illustrated in FIG. 7, and/or a combination of two or more of the aforementioned processes. When executed by processing system 905, software 903 directs processing system 905 to operate as described herein for at least the various processes, operational scenarios, and sequences discussed in the foregoing implementations. Computing system 901 may optionally include additional devices, features, or functionality not discussed here for purposes of brevity.

Processing system 905 may comprise a micro-processor and other circuitry that retrieves and executes software 903 from storage system 902. Processing system 905 may be implemented within a single processing device but may also be distributed across multiple processing devices or sub-systems that cooperate in executing program instructions. Examples of processing system 905 include general purpose central processing units, graphical processing units, application specific processors, and logic devices, as well as any other type of processing device, combinations, or variations thereof.

Storage system 902 may comprise any computer readable storage media that is readable by processing system 905 and capable of storing software 903. Storage system 902 may include volatile and nonvolatile, removable, and non-removable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 902 may also include computer readable communication media over which at least some of software 903 may be communicated internally or externally. Storage system 902 may be implemented as a single storage device but may also be implemented across multiple storage devices or sub-systems co-located or distributed relative to each other. Storage system 902 may comprise additional elements, such as a controller, capable of communicating with processing system 905 or possibly other systems.

Software 903 (histogram generation process 910) may be implemented in program instructions and among other functions may, when executed by processing system 905, direct processing system 905 to operate as described with respect to the various operational scenarios, sequences, and processes illustrated herein. For example, software 903 may include program instructions for implementing a histogram generation process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 903 may include additional processes, programs, or components, such as operating system software, virtualization software, or other application software. Software 903 may also comprise firmware or some other form of machine-readable processing instructions executable by processing system 905.

In general, software 903 may, when loaded into processing system 905 and executed, transform a suitable apparatus, system, or device (of which computing system 901 is representative) overall from a general-purpose computing system into a special-purpose computing system customized to model data records associated with a data pipeline using hierarchical histograms as described herein. Indeed, encoding software 903 on storage system 902 may transform the physical structure of storage system 902. The specific transformation of the physical structure may depend on various factors in different implementations of this description. Examples of such factors may include, but are not limited to, the technology used to implement the storage media of storage system 902 and whether the computer-storage media are characterized as primary or secondary storage, as well as other factors.

For example, if the computer readable storage media are implemented as semiconductor-based memory, software 903 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 904 may include communication connections and devices that allow for communication with other computing systems (not shown) over communication networks (not shown). Examples of connections and devices that together allow for inter-system communication may include network interface cards, antennas, power amplifiers, RF circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 901 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of network, or variation thereof. The aforementioned communication networks and protocols are well known and need not be discussed at length here.

The data processing circuitry described above comprises computer hardware and software that form special-purpose data monitoring circuitry to generate hierarchical histograms for probability density estimations to model the operation of a data pipeline. The computer hardware comprises processing circuitry like CPUs, GPUs, transceivers, bus circuitry, and memory. To form these computer hardware structures, semiconductors like silicon or germanium are positively and negatively doped to form transistors. The doping comprises ions like boron or phosphorus that are embedded within the semiconductor material. The transistors and other electronic structures like capacitors and resistors are arranged and metallically connected within the semiconductor to form devices like logic circuitry and storage registers. The logic circuitry and storage registers are arranged to form larger structures like control units, logic units, and Random-Access Memory (RAM). In turn, the control units, logic units, and RAM are metallically connected to form CPUs, GPUs, transceivers, bus circuitry, and memory.

In the computer hardware, the control units drive data between the RAM and the logic units, and the logic units operate on the data. The control units also drive interactions with external memory like flash drives, disk drives, and the like. The computer hardware executes machine-level software to control and move data by driving machine-level inputs like voltages and currents to the control units, logic units, and RAM. The machine-level software is typically compiled from higher-level software programs. The higher-level software programs comprise operating systems, utilities, user applications, and the like. Both the higher-level software programs and their compiled machine-level software are stored in memory and retrieved for compilation and execution. On power-up, the computer hardware automatically executes physically-embedded machine-level software that drives the compilation and execution of the other computer software components which then assert control. Due to this automated execution, the presence of the higher-level software in memory physically changes the structure of the computer hardware machines into special-purpose network circuitry to generate hierarchical histograms for probability density estimations to model the operation of a data pipeline.

The above description and associated figures teach the best mode of the invention. The following claims specify the scope of the invention. Note that some aspects of the best mode may not fall within the scope of the invention as specified by the claims. Those skilled in the art will appreciate that the features described above can be combined in various ways to form multiple variations of the invention. Thus, the invention is not limited to the specific embodiments described above, but only by the following claims and their equivalents.

What is claimed is:

1. A method of operating data monitoring system to generate multi-layered histograms, the method comprising:
reading a data record associated with a data pipeline and modeling the data record as a histogram wherein the histogram comprises histogram buckets that categorize data values of the data record;
scanning the histogram buckets and determining when a proportion of the data values assigned to one of the histogram buckets exceeds a threshold value; and
when the proportion of the data values assigned to the one of the histogram buckets exceeds the threshold value, modeling the data values assigned to the one of the histogram buckets as a subsidiary histogram wherein the subsidiary histogram comprises subsidiary histogram buckets that categorize the data values assigned to the one of the histogram buckets.

2. The method of claim 1 further comprising:
reading a second data record associated with the data pipeline and modeling the second data record as a second histogram wherein the second histogram comprises second histogram buckets that categorize second data values of the second data record;
scanning the second histogram buckets and determining when a proportion of the second data values assigned to one of the second histogram buckets exceeds the threshold value; and
when the proportion of the second data values assigned to the one of the second histogram buckets exceeds the threshold value, modeling the second data values assigned to the one of the second histogram buckets as a second subsidiary histogram wherein the second subsidiary histogram comprises second subsidiary histogram buckets that categorize the second data values assigned to the one of the second histogram buckets.

3. The method of claim 2 further comprising:
computing a statistical distance between the histogram and the second histogram to determine an amount of difference between the data record and the second data record;
applying the amount of difference to a change threshold;
when the amount of difference exceeds the change threshold, correlating the amount of difference to a change in the data pipeline and transferring a notification indicating the change.

4. The method of claim 3 wherein:
the data record comprises a chronologically first data record; and
the second data record comprises a chronologically subsequent data record.

5. The method of claim 1 further comprising:
determining a probability density estimation for the data record based on a distribution of the data values in the histogram and the subsidiary histogram; and
generating an output model for the data pipeline based on the probability density estimation.

6. The method of claim 1 wherein the data record comprises an output data set generated by the data pipeline.

7. The method of claim 1 wherein the data values comprise numeric data.

8. A data monitoring system to generate multi-layered histograms, the system comprising:
a memory that stores executable components; and
a processor, operatively coupled to the memory, that executes the executable components, the executable components comprising:
a modeling component configured to:
read a data record associated with a data pipeline and model the data record as a histogram wherein the histogram comprises histogram buckets that categorize data values of the data record;
scan the histogram buckets and determine when a proportion of the data values assigned to one of the histogram buckets exceeds a threshold value; and
model the data values assigned to the one of the histogram buckets as a subsidiary histogram when the proportion of the data values assigned to the one of the histogram buckets exceeds the threshold value wherein the subsidiary histogram comprises subsidiary histogram buckets that categorize the data values assigned to the one of the histogram buckets.

9. The system of claim 8 wherein the modeling component is further configured to:
read a second data record associated with the data pipeline and model the second data record as a second histogram wherein the second histogram comprises second histogram buckets that categorize second data values of the second data record;
scan the second histogram buckets and determine when a proportion of the second data values assigned to one of the second histogram buckets exceeds the threshold value; and
model the second data values assigned to the one of the second histogram buckets as a second subsidiary histogram when the proportion of the second data values assigned to the one of the second histogram buckets exceeds the threshold value wherein the second subsidiary histogram comprises second subsidiary histogram buckets that categorize the second data values assigned to the one of the second histogram buckets.

10. The system of claim 9 wherein the modeling component is further configured to:
compute a statistical distance between the histogram and the second histogram to determine an amount of difference between the data record and the second data record;
apply the amount of difference to a change threshold; and
determine when the amount of difference exceeds the change threshold; and
when the amount of difference exceeds the change threshold, correlate the amount of difference to a change in the data pipeline and transfer a notification indicating the change.

11. The system of claim 10 wherein:
the data record comprises a chronologically first data record; and
the second data record comprises a chronologically subsequent data record.

12. The system of claim 8 wherein the modeling component is further configured to:
determine a probability density estimation for the data record based on a distribution of the data values in the histogram and the subsidiary histogram; and
generate an output model for the data pipeline based on the probability density estimation.

13. The system of claim 8 wherein the data record comprises an output data set generated by the data pipeline.

14. The method of claim 1 wherein the data values comprise numeric data.

15. A non-transitory computer-readable medium storing instructions to generate multi-layered histograms, wherein the instructions, in response to execution by one or more processors, cause the one or more processors to drive a system to perform operations, the operations comprising:
reading a data record associated with a data pipeline and modeling the data record as a histogram wherein the histogram comprises histogram buckets that categorize data values of the data record;
scanning the histogram buckets and determining when a proportion of the data values assigned to one of the histogram buckets exceeds a threshold value; and
when the proportion of the data values assigned to the one of the histogram buckets exceeds the threshold value, modeling the data values assigned to the one of the histogram buckets as a subsidiary histogram wherein the subsidiary histogram comprises subsidiary histogram buckets that categorize the data values assigned to the one of the histogram buckets.

16. The non-transitory computer-readable medium of claim 15, the operations further comprising:
reading a second data record associated with the data pipeline and modeling the second data record as a second histogram wherein the second histogram comprises second histogram buckets that categorize second data values of the second data record;
scanning the second histogram buckets and determining when a proportion of the second data values assigned to one of the second histogram buckets exceeds the threshold value; and
when the proportion of the second data values assigned to the one of the second histogram buckets exceeds the threshold value, modeling the second data values assigned to the one of the second histogram buckets as a second subsidiary histogram wherein the second subsidiary histogram comprises second subsidiary histogram buckets that categorize the second data values assigned to the one of the second histogram buckets.

17. The non-transitory computer-readable medium of claim 16, the operations further comprising:
computing a statistical distance between the histogram and the second histogram to determine an amount of difference between the data record and the second data record;
applying the amount of difference to a change threshold;
when the amount of difference exceeds the change threshold, correlating the amount of difference to a change in the data pipeline and transferring a notification indicating the change.

18. The non-transitory computer-readable medium of claim 17 wherein:
the data record comprises a chronologically first data record; and
the second data record comprises a chronologically subsequent data record.

19. The non-transitory computer-readable medium of claim 15, the operations further comprising:
determining a probability density estimation for the data record based on a distribution of the data values in the histogram and the subsidiary histogram; and
generating an output model for the data pipeline based on the probability density estimation.

20. The non-transitory computer-readable medium of claim 15 wherein:
the data record comprises an output data set generated by the data pipeline; and
the data values comprise numeric data.
